(19) United States
(12) Patent Application Publication
(10) Pub. No.: US 2008/0153198 A1
(43) Pub. Date: Jun. 26, 2008

(54) Method for Fabricating CMOS Image Sensor

(76) Inventor: Sang Tae Moon, Seo-gu (KR)

Correspondence Address: SALIWANCHIK LLOYD & SALIWANCHIK;A PROFESSIONAL ASSOCIATION, PO BOX 142950, GAINESVILLE, FL, 32614-2950, US

(21) Appl. No.: 11/854,860

(22) Filed: Sep. 13, 2007

(30) Foreign Application Priority Data
Dec. 26, 2006 (KR) 10-2006-0134198

(51) Int. Cl. H01L 21/3205

(52) U.S. Cl. 438/98; 257/E21.294

(57) ABSTRACT

A method for fabricating a CMOS image sensor according to an embodiment includes: forming an interlayer dielectric layer over a metal wiring on a semiconductor substrate; forming a capping layer on the interlayer dielectric layer; forming a hard mask layer on the capping layer; forming a contact hole by selectively removing the hard mask layer, the capping layer, and the interlayer dielectric layer so that predetermined portions of the metal wiring and the surface of the semiconductor substrate are exposed; and forming a tungsten plug inside the contact hole by depositing a tungsten film over the contact hole and the semiconductor substrate and performing a CMP process.

### CROSS-REFERENCE TO RELATED APPLICATION

The present application claims the benefit under 35 U.S.C. §119 of Korean Patent Application No. 10-2006-0134198, filed Dec. 26, 2006, which is hereby incorporated by reference in its entirety.

### BACKGROUND

In general, in order to improve image quality, which is a decisive factor in the quality of a CMOS (complementary metal oxide semiconductor) image sensor, the distance between a photodiode and a microlens should be the same as the focal length of the microlens.

To this end, one approach is to reduce the thicknesses of an interlayer dielectric layer and a planarization layer.

Generally, BPSG (Boro-Phospho-Silicate-Glass) is used as the material of the planarization layer, and USG (Un-doped Silicate Glass) is used as the material of a capping layer.

However, as a result of reducing the thickness of the USG, the photo align key portion of the metal wiring of a bottom layer, where the size of a pattern is large and the density of the pattern is relatively high, in a process of performing a CMP (Chemical Mechanical Polishing) for tungsten becomes excessively corroded so that the align key may not be recognized.

Since the polishing rate of the BPSG is faster than that of the USG, if the thickness of the USG becomes thin due to the corrosion in performing the CMP process for the tungsten film, the entire USG film is polished and the BPSG film also starts to be polished so that the corrosion rapidly increases.

As a result, a step difference is removed in an align pattern portion needing to secure a step difference with a predetermined size. Therefore an alignment failure occurs.

FIGS. 1 to 4 are cross-sectional views of a process showing a method for fabricating the CMOS image sensor according to the related art.

Referring to FIG. 1, a metal film is deposited on a semiconductor substrate 11, and a metal wiring 12 is formed by selectively patterning the metal film by means of photo and etching processes.

Here, the metal wiring 12 may be a wiring for electrically connecting a photodiode and various transistors formed on the semiconductor substrate 11.

Referring to FIG. 2, a BPSG film 13 is formed over the metal wiring 12 and the semiconductor substrate 11, and the surface of the BPSG film is planarized by performing a CMP process over the BPSG film 13.

That is, if the BPSG film 13 is formed over the metal wiring 12 and the semiconductor substrate 11, a portion of the BPSG film 13 above the lower metal wiring 12 is projected more than its other portions to form a mountain-like shape. Therefore, the CMP process is performed over the BPSG film to planarize the surface thereof before performing a subsequent process.

Referring to FIG. 3, a USG film 14 is formed on the BPSG film 13, and a contact hole 15 is formed by selectively removing the USG film 14 and the BPSG film 13 so that predetermined portions of the metal wiring 12 and the surface of the semiconductor substrate 11 are exposed by means of photo and etching processes.

Referring to FIG. 4, a tungsten film is deposited over the contact hole 15 and the semiconductor substrate 11, and a tungsten plug 16 is formed inside of the contact hole 15 by performing a CMP process over the tungsten film, targeting the upper surface of the USG film 14.

However, the method for fabricating the CMOS image sensor according to the related art as described above has a problem as follows.

That is, due to corrosion in performing the CMP process for the tungsten film, the entire USG film 14 is polished away and the BPSG film also becomes polished so that the corrosion rapidly increases. As a result, a step (not shown) is removed in an align pattern portion needing to secure a step with a predetermined size so that a failure of alignment may occur.

### BRIEF SUMMARY

Embodiments of the present invention provide a method for fabricating a CMOS image sensor capable of improving the yield of a product by reducing the amount of corrosion of an align key pattern. In an embodiment, the amount of corrosion of an align key can be reduced in a CMP process for a tungsten film to prevent or inhibit an alignment failure.

The method for fabricating the CMOS image sensor according to an embodiment includes: forming a metal wiring on a semiconductor substrate; forming an interlayer dielectric layer over the metal wiring and the semiconductor substrate; forming a capping layer on the interlayer dielectric layer; forming a hard mask layer on the capping layer; forming a contact hole by selectively removing the hard mask layer, the capping layer, and the interlayer dielectric layer so that predetermined portions of the metal wiring and the surface of the semiconductor substrate are exposed; and forming a tungsten plug inside the contact hole by depositing a tungsten film over the contact hole and the semiconductor substrate and performing a CMP (chemical mechanical polishing) process.

### BRIEF DESCRIPTION OF THE DRAWINGS

FIGS. 1 to 4 are cross-sectional views of a process showing a method for fabricating a CMOS image sensor according to the related art.

FIGS. 5 to 9 are cross-sectional views of a process showing a method for fabricating a CMOS image sensor according to an embodiment of the present invention.

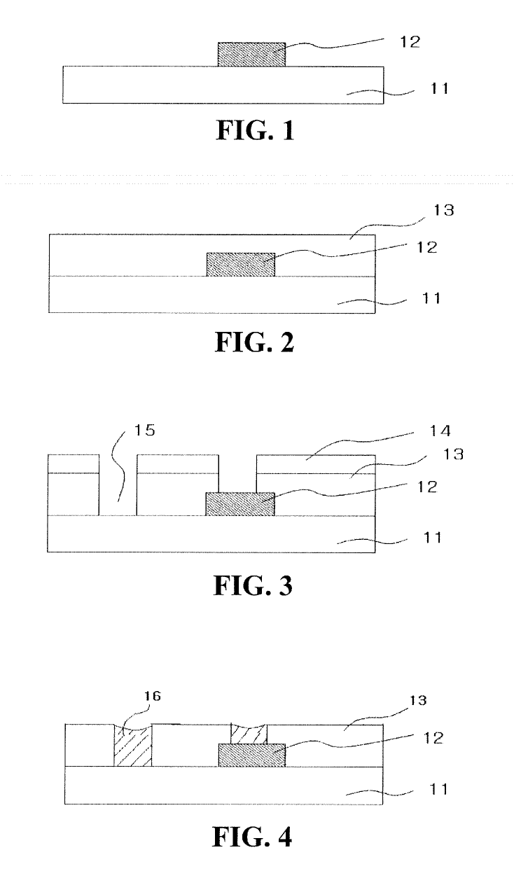

### DETAILED DESCRIPTION

Hereinafter, a method for fabricating a CMOS image sensor according to embodiments of the present invention will be described in more detail with reference to accompanying drawings.

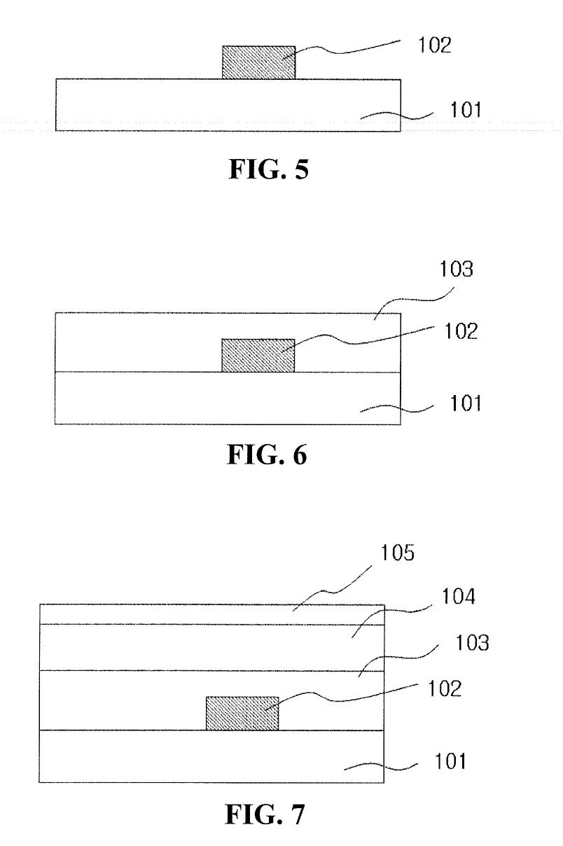

FIGS. 5 to 9 are cross-sectional views a method for fabricating a CMOS image sensor according to an embodiment of the present invention.

Referring to FIG. 5, a metal wiring can be formed on a semiconductor substrate. In one embodiment, the metal wiring can be a metal wiring 102 for electrically connecting to a photodiode and/or various transistors formed on the semiconductor substrate 101.

In an embodiment, a metal film can be deposited on the semiconductor substrate 101 on which a photodiode (not shown) and various transistors (not shown) are formed, and the metal wiring 102 can be formed by selectively patterning the metal film by means of photo and etching processes.

Referring to FIG. 6, an interlayer dielectric layer 103 can be formed over the metal wiring 102. The interlayer dielectric layer can be a BPSG film and formed at a thickness of 4700 to 5700 Å over the metal wiring 102 and the semiconductor substrate 101. The surface of the BPSG film 103 can be planarized by performing a CMP process.

That is, if the BPSG film 103 is formed over the metal wiring 102 and the semiconductor substrate 101, a portion of the BPSG film 103 above the lower metal wiring 102 projects more than its other portions to form a mountain-like shape. Therefore, the CMP process is performed to planarize the surface of the BPSG film 103 for a subsequent process.

In one embodiment, the thickness of the BPSG film 103 removed by means of the CMP process may be on the order of 1700 to 2700 Å such that the BPSG film 103 having the thickness of about 3000 Å remains.

Referring to FIG. 7, a cap layer 104 can be formed on the interlayer dielectric layer 103. The cap layer 104 can be a USG film formed at a thickness of 1500 to 3000 Å on the BPSG film 103.

According to an embodiment, the USG film (104) uses silicon-rich oxide in order to inhibit the diffusion of the fluorine base of a FSG film that can be used as a subsequent layer.

Thereafter, a hard mask layer 105 can be formed on the cap layer 104. The hard mask layer 105 can be a SiN film formed at a thickness of 400 to 600 Å on the USG film 104.

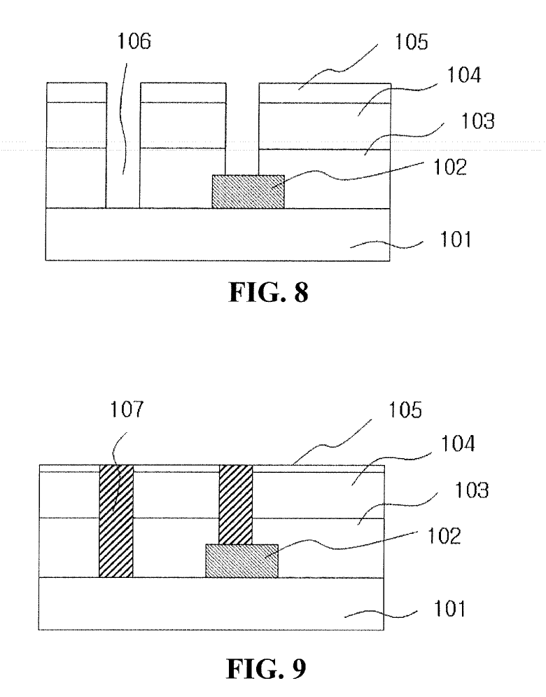

Referring to FIG. 8, a contact hole 106 can be formed by selectively removing the SiN film 105, the USG film 104, and the BPSG film 103 so that predetermined portions of the metal wiring 102 and the surface of the semiconductor substrate 101 are exposed. This can be accomplished by means of photo and etching processes.

Referring to FIG. 9, a tungsten film can be deposited on the substrate 101 including in the contact hole 106. In an embodiment, the tungsten film is formed to a thickness of 1600 to 4500 Å. A tungsten plug 107 is formed inside of the contact hole 106 by performing a CMP process over the tungsten film, targeting the upper surface of the SiN film 105.

At this time, the amount of the SiN film 105 removed in the CMP process of the tungsten film may be about 300 to 500 Å.

As described above, the method for fabricating the CMOS image sensor according to embodiments has an effect as follows.

That is, the corrosion amount of an align key pattern is reduced so that alignment failure occurring in a metal wiring forming process can be prevented in advance, thereby making it possible to improve the productivity of a product.

Any reference in this specification to “one embodiment,” “an embodiment,” “example embodiment,” etc., means that a particular feature, structure, or characteristic described in connection with the embodiment is included in at least one embodiment of the invention. The appearances of such phrases in various places in the specification are not necessarily all referring to the same embodiment. Further, when a particular feature, structure, or characteristic is described in connection with any embodiment, it is submitted that it is within the purview of one skilled in the art to effect such feature, structure, or characteristic in connection with other ones of the embodiments.

Although embodiments have been described with reference to a number of illustrative embodiments thereof, it should be understood that numerous other modifications and embodiments can be devised by those skilled in the art that will fall within the spirit and scope of the principles of this disclosure. More particularly, various variations and modifications are possible in the component parts and/or arrangements of the subject combination arrangement within the scope of the disclosure, the drawings and the appended claims. In addition to variations and modifications in the component parts and/or arrangements, alternative uses will also be apparent to those skilled in the art.

What is claimed is:

1. A method for fabricating a CMOS image sensor, comprising:
forming an interlayer dielectric layer over a metal wiring on a semiconductor substrate;
forming a capping layer on the interlayer dielectric layer;
forming a hard mask layer on the capping layer;
forming a contact hole by selectively removing the hard mask layer, the capping layer, and the interlayer dielectric layer to expose a predetermined portion of the metal wiring; and
forming a tungsten plug inside the contact hole by depositing a tungsten film on the semiconductor substrate including the contact hole and performing a CMP (chemical mechanical polishing) process.

2. The method according to claim 1, further comprising planarizing the surface of the interlayer dielectric layer before forming the capping layer.

3. The method according to claim 1, wherein the interlayer dielectric layer is a BPSG film having a thickness of 4700 to 5700 Å.

4. The method according to claim 1, wherein the capping layer is a USG film having a thickness of 1500 to 3000 Å.

5. The method according to claim 1, wherein the hard mask layer is a SiN film having a thickness of 400 to 600 Å.

6. The method according to claim 1, wherein the metal wiring is formed on a substrate having a photodiode and transistors to form electrical connections.

7. The method according to claim 1, wherein during performing the CMP process, the hard mask layer inhibits corrosion of the interlayer dielectric layer.
